(19) United States
(12) Patent Application Publication
(10) Pub. No.: US 2024/0086213 A1
(43) Pub. Date: Mar. 14, 2024

(54) METHOD AND SYSTEM FOR ACCELERATOR EMULATION

(71) Applicants: Lemon Inc., Grand Cayman (KY); Beijing Volcano Engine Technology Co., Ltd., BEIJING (CN)

(72) Inventors: Hui Zhang, Los Angeles, CA (US); Fei Liu, Los Angeles, CA (US); Ping Zhou, Los Angeles, CA (US); Chul Lee, Los Angeles, CA (US); Bo Li, Beijing (CN); Shan Xiao, Beijing (CN)

(21) Appl. No.: 18/484,962

(22) Filed: Oct. 11, 2023

(51) Int. Cl. G06F 9/455; G06F 9/50

(52) U.S. Cl. CPC G06F 9/455; G06F 9/5027; G06F 2209/509

(57) ABSTRACT

Methods and systems for emulating a hardware accelerator is provided. When executed by a computer, the platform includes a plurality of computational resources provided by the computer; a hardware emulator operated on a first computational resource of the plurality of computational resources; and an accelerator being emulated in the platform and operated on a second computational resource of the plurality of computational resources, the accelerator being configured to execute an offloading operation.

### FIELD

The embodiments described herein pertain generally to an emulation system for emulating a hardware accelerator. More specifically, the embodiments described herein pertain to methods and systems that separate computational resources for the hardware emulator and the emulated accelerator for accurately projecting and evaluating the performance of the emulated accelerator.

### BACKGROUND

Hardware offloading includes delegating computing tasks from a central processing unit (CPU) to a hardware accelerator that is a specialized hardware component that includes components that may accelerate data processing and analysis, improve performance, and reduce power consumption. The accelerator can be designed particularly for certain data processing functions. Hardware prototyping and/or proof of concept designs of an accelerator can involve substantial time and capital investment.

### SUMMARY

The embodiments described herein pertain generally to an emulation system for emulating a hardware accelerator. More specifically, the embodiments described herein pertain to methods and systems for having separate computational resources for the hardware emulator and the emulated accelerator for accurately projecting and evaluating the performance of the emulated accelerator.

In data processing operations (e.g., big data, machine learning, large data analytics, cloud computing, or the like), hardware offloading can be utilized to accelerate the data processing operations. A host device may send data processing operations to be offloaded to a hardware accelerator, which may be less energy intensive, faster, and more cost effective than executing the data processing operations on a general purpose central processing unit (CPU).

Emulation of the hardware and software co-design system can be provided to evaluate the system that executes the offloading operation. The emulation can include emulating of a hardware accelerator to evaluate the performance of the hardware accelerator being emulated.

It is appreciated that an emulation of an accelerator can generally consume a substantial amount of computational power for hardware emulators such as the quick emulator (QEMU) or any other general hardware emulation systems.

In embodiments of the disclosed emulation platform, the emulation of the accelerator can be provided and operated on a computational resource that is separate, or independent from, the computational resources provided to other components (e.g., the controller for the hardware emulator, the host device, or the like). Such an arrangement can be configured for avoiding the emulated accelerator competing for computational resources, for more accurately emulating the performance of the accelerator, and the like. In some embodiments, with a separated computational resource, the emulation platform can adjust the amount of computational power available to the emulated accelerator independently from other variables or components in the platform. Such adjustments can enable the evaluation of the performance of the emulated accelerator relative to a range of computational power provided to the accelerator, e.g., for optimizing the amount of computational power to be provided to the emulated accelerator.

In an embodiment, a platform for emulating a hardware accelerator is provided. When executed by a computer, the platform includes a hardware emulator, configured to emulate an accelerator, operated on a first computational resource of a plurality of computational resources provided by the computer; and the accelerator being emulated in the platform and operated on a second computational resource of the plurality of computational resources, the accelerator being configured to emulate an execution of an offloading operation by the second computational resource that is separate from the first computational resource.

In an embodiment, the hardware emulator includes a quick emulator (QEMU) providing an emulation of a controller operating on the first computational resource; and the QEMU emulates the accelerator for an emulation of executing the offloading operation on the second computational resource.

In an embodiment, the accelerator includes the offloading operation includes decompressing, filtering, or decoding.

In an embodiment, the accelerator is emulated as an NVMe device, and the hardware emulator emulates an NVMe controller for an emulation of receiving an offloading command for performing the offloading operation.

In an embodiment, the hardware emulator emulates a firmware having instructions for an emulation of operating the accelerator to execute the offloading operation.

In an embodiment, the hardware emulator is provided with a main loop thread, ran by the first computational resource, for emulating receiving of an offloading command for emulating an execution of the offloading operation, and for emulating providing a callback function for communicating a function complete message.

In an embodiment, the platform includes a host device in communication with the hardware emulator that is configured to receive an offloading command from the host device.

In an embodiment, the hardware emulator is provided with a main loop thread, ran by the first computational resource, for emulating parsing of an offloading command.

In an embodiment, the platform is configured to adjust a computational power available to the accelerator for evaluating offloading performance of the accelerator relative to an amount of the computational power available to the accelerator.

In an embodiment, a method of emulating hardware offloading is provided. The method includes emulating a running of a hardware emulator on a first computational resource of a plurality of computational resources; emulating an accelerator; emulating a running of the accelerator on a second computational resource of the plurality of computational resources; and emulating an executing an offloading command using the accelerator.

In an embodiment, the offloading command includes decompressing, filtering, or decoding.

In an embodiment, the method includes emulating a receiving of the offloading command from a host device communicating with the hardware emulator.

In an embodiment, the method includes emulating a transmitting of the offloading command to a main loop thread run by the first computational resource; emulating a receiving of the offloading command for performing an offloading operation; and instructing the accelerator to execute the offloading operation according to the offloading command.

In an embodiment, the method includes emulating a triggering of a callback function to communicate a function complete message to a host device when an offloading operation is completed according to the offloading command.

In an embodiment, the method includes emulating a recording of a processing time for executing the offloading command using the accelerator.

In an embodiment, the method includes adjusting an amount of computational power available to the second computational resource for evaluating offloading performance of the accelerator relative to an amount of the computational power available to the accelerator.

In an embodiment, a computer-readable medium containing instructions that, when executed by a processor, direct the processor to run a hardware emulator on a first computational resource of a plurality of computational resources; emulate an accelerator; emulate an operation of the accelerator on a second computational resource of the plurality of computational resources; and emulate an execution of an offloading command using the accelerator.

In an embodiment, the computer-readable medium further containing instructions that, when executed by the processor, direct the processor to emulate a receiving of the offloading command from a host device communicating with the hardware emulator.

In an embodiment, the computer-readable medium further containing instructions that, when executed by the processor, direct the processor to emulate a transmission of the offloading command to a main loop thread run by the first computational resource; emulate a receiving of the offloading command to obtain an offloading operation; and emulate an instruction of the accelerator to execute the offloading operation.

In an embodiment, the computer-readable medium of any one further containing instructions that, when executed by the processor, direct the processor to emulate a receiving of data by direct memory access (DMA) from a host device; emulate a processing of the data according to the offloading command to obtain processed data; emulate a sending of the processed data by DMA to the host device; and emulate a triggering of a callback function to communicate a function complete message to the host device.

In an embodiment, the computer-readable medium of any one further containing instructions that, when executed by the processor, direct the processor to adjust an amount of computational power available to the second computational resource for evaluating offloading performance of the accelerator relative to an amount of the computational power available to the accelerator.

### BRIEF DESCRIPTION OF THE DRAWINGS

The accompanying drawings illustrate various embodiments of systems, methods, and embodiments of various other aspects of the disclosure. Any person with ordinary skills in the art will appreciate that the illustrated element boundaries (e.g. boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Non-limiting and non-exhaustive descriptions are described with reference to the following drawings. The components in the figures are not necessarily to scale, emphasis instead being placed upon illustrating principles. In the detailed description that follows, embodiments are described as illustrations only since various changes and modifications may become apparent to those skilled in the art from the following detailed description.

FIG. 1 is a schematic view of the architecture of an emulation platform, according to an embodiment.

FIG. 2 is a schematic diagram for data flow in an emulation platform, according to an embodiment.

FIG. 3 illustrates a data process flow in an emulation platform, according to an embodiment.

FIG. 4 is a flowchart for illustrating a method of emulating hardware offloading, according to an embodiment.

FIG. 5 illustrates a schematic structural diagram of an electronic device 800, according to an embodiment.

Like reference numbers represent like parts throughout.

### DETAILED DESCRIPTION

The embodiments described herein pertain generally to an emulation system for emulating a hardware accelerator. More specifically, the embodiments described herein pertain to methods and systems for having separate computational resources for the hardware emulator and the emulated accelerator for accurately projecting and evaluating the performance of the emulated accelerator.

In the following detailed description, particular embodiments of the present disclosure are described herein with reference to the accompanying drawings, which form a part of the description. In this description, as well as in the drawings, like-referenced numbers represent elements that may perform the same, similar, or equivalent functions, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not intended to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

It is to be understood that the disclosed embodiments are merely examples of the disclosure, which may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure.

Additionally, the present disclosure may be described herein in terms of functional block components and various processing steps. It should be appreciated that such functional blocks may be realized by any number of hardware and/or software components configured to perform the specified functions.

The scope of the disclosure should be determined by the appended claims and their legal equivalents, rather than by the examples given herein. For example, the steps recited in any method claims may be executed in any order and/or concurrently and are not limited to the order presented in the claims. Moreover, no element is essential to the practice of the disclosure unless specifically described herein as “critical” or “essential”.

As referenced herein, a “network” or a “computer network system” is a term of art and may refer to interconnected computing devices that may exchange data and share resources with each other. It is to be understood that the networked devices may use a system of rules (e.g., communications protocols, etc.), to transmit information over wired or wireless technologies.

As referenced herein, a “NVMe protocol or interface” may refer to non-volatile memory express protocol that provides a quick interface between computer processing units and storage devices, such as solid-state devices (SSDs). The NVMe protocol or interface may use a Peripheral Component Interconnect Express (PCIe) bus that provides a leaner interface for accessing the SSDs.

In some computer networking systems, such as, cloud-based storage environments, e.g., in a data center or in a server system, hardware offloading operations may be provided such that a host device having a controller, such as, a central processing unit (CPU), may offload certain functionalities or operations from the host device to a controller (or CPU) on a server connected to the storage device(s).

For example, in some embodiments, the processor-enabled server, e.g., having hardware, software, and/or firmware operations, may include various hardware offloading engines, such as data streaming accelerators and in-memory analytics accelerators. In an example embodiment, the host device may be designed, programmed, or otherwise configured to provide (e.g., transmit/send) an offloading command to the server for hardware offloading operations/functionalities to the hardware offloading engines on the processor-enabled server (and/or the processor-enabled server may be designed, programmed, or otherwise configured to fetch the offloading command). The emulation platform disclosed herein may be configured to emulate such computer networking systems.

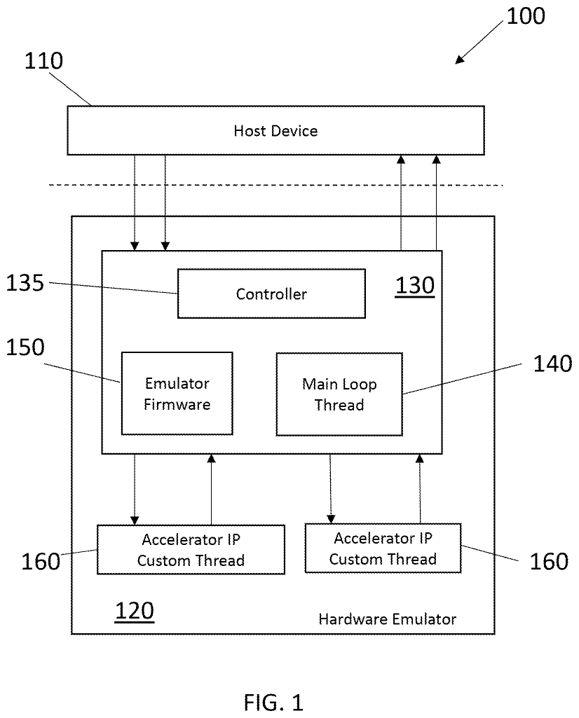

FIG. 1 is a schematic view of the architecture of an emulation platform 100, according to an embodiment. The emulation platform 100 provides an emulation for one or more software and/or hardware components or devices, e.g., for testing, prototyping, troubleshooting, and/or the like. For example, the emulation can be conducted for projecting and/or evaluating the performance of, or the compatibility among, hardware and software components in a system running the hardware and software components. The hardware and software components can be prototyped devices, or existing devices included in a proposed system, configuration such that issues or bottlenecks in the software and/or hardware design, their integration, and the system architecture may be identified, e.g., by monitoring the performance of components/systems in the emulation.

Evaluation and performance optimization maybe conducted with the emulation, avoiding and/or reducing the need for physical prototyping. The emulation of software and/or hardware components or devices includes the emulation of one or more hardware accelerators (or accelerators) such as Graphics Processing Units (GPUs), Field-Programmable Gate Arrays (FPGAs), or Application-Specific Integrated Circuits (ASICs), or the like.

As shown in FIG. 1, the emulation platform 100 can be configured to emulate one or more hardware offloading operations executed by one or more accelerators 160 that run on a computational resource separated from the computational resource running the hardware emulator 120. In an embodiment, the emulation platform 100 can include a host device 110 communicating with the hardware emulator 120. The hardware emulator 120 can include a controller module 130 having a controller 135, a main loop thread 140, and an emulator firmware 150, and one or more emulated accelerator 160.

In an embodiment, the emulation platform 100 can be provided on a physical computing device such as a computer, a network of computers, a cloud computing center, or the like. In an embodiment, the emulation platform 100 can include software module(s) that create the emulation. The emulation platform 100 can include a hardware emulator 120 for creating the emulation. In an embodiment, the hardware emulator 120 in the emulation platform 100 can be QEMU.

The emulation platform 100 can be provided with one or more computational resources to provide computational power for emulating the hardware and software components in the emulation platform 100. In an embodiment, the emulation platform 100 is provided with the one or more computational resources for the hardware emulator 120.

The computational resource includes one or more CPUs each having one or more cores that provide one or more threads for executing instructions and/or data processing operations such as controlling the hardware emulator 120, operating one or more emulated accelerators 160, decompression, filtering, decoding, and/or the like.

In an embodiment, the physical computing device can execute instructions provided by a non-transitory computer readable medium to create, establish, and/or run the emulation platform 100 that is configured to provide the hardware emulator 120 and to emulate the one or more accelerators 160.

The host device 110 can be a physical or virtual computing device that requests a data processing operation. In an embodiment, the host device 110 can emulate a request of a data processing operation for an emulation of the running an execution engine for data management hosted on the host device 110

In an embodiment, the host device 110 is configured to communicate a data processing command (e.g., through the hardware accelerator 120) to an emulation of an accelerator (e.g., accelerators 160) for evaluating the preference of the offloading operation, the design of accelerator, the interaction of the overall system, and/or the like.

The host device 110 utilizes one or more communication protocols for communicating with the hardware emulator 120 and/or its components. In an embodiment, the communication protocol can be the NVMe protocol, and the host device 110 is emulated as a virtual NVMe device. In an embodiment, the host device 110 can be configured to end a commend (e.g., a data operation command) to the hardware emulator 120. Direct memory access (DMA) can be utilized for transmitting data between the host device 110 and the hardware emulator 120. In an embodiment, the host device 110 is configured to receive a Complete Queue Entry (CQE) from the hardware emulator 120 once the emulation of the offloading of one or more data processing operations is completed.

The hardware emulator 120 can be any general purpose emulator suitable for creating emulation of hardware and software components of a computing system or computing device, such as an accelerator. In an embodiment, the hardware emulator 120 includes a QEMU environment configured to provide emulation of one or more hardware devices and its hardware and software components. The hardware emulator 120 is configured to emulate one or more accelerators 160. The accelerators 160 are hardware accelerator that include software and/or hardware components or devices such as GPUs, FPGAs, ASICs, and/or the like. The hardware emulator 120 can also provide a controller module 130 for operating the emulation of the accelerators 160.

The hardware emulator 120 can be provided with a physical or hardware system that provides computational power from one or more computational resources. The computational resource can be one or more CPUs having one or more cores providing one or more computational threads. It is appreciated that computational resource can be any device or structure that supports the operation emulation of the hardware emulator 120, the accelerator(s) 160, and/or the like.

The computational resources of the hardware emulator 120 can include a first computational resource and a second computational resource separate from the first computational resource. For example, the first computational resource may be a first thread provided by a CPU and a second computational resource may be a second thread provided by the same CPU or a different CPU providing the first thread.

The hardware emulator 120 is configured such that, the first computational resource of the hardware emulator 120 emulates and/or operates the hardware emulator 120, and the second computational resource operates the one of more accelerators 160. In an embodiment, the second computational resource operates the emulation of the one of more accelerators 160. The second computational resource can be provided to the hardware emulator 120 as a virtual CPU core/thread powered by the second computational resource, separate from the first computational resource. In an embodiment, a separate computational resource is provided respectively for each of the emulated accelerators 160 and the hardware emulator 120. In an embodiment, the first computational resource is an emulator thread that operates the hardware emulator 120, and the second computational resource is an accelerator thread (different from the emulator thread) operates the emulated accelerator 160. In an embodiment, a plurality of accelerator threads each operates one of the one or more emulated accelerators 160.

Computational resources may be added or removed from the hardware emulator 120 to increase or decrease the computational power available to the hardware emulator 120, for example, by increasing or decreasing the number of cores in the CPU for the hardware emulator 120, increasing or decreasing the number of cores activated on the CPU for the hardware emulator 120, replacing the CPU with a CPU having more or less cores, or the like. By making such adjustments to computational resources, more or less computational power can be made available to the second computational resource for operating the accelerator(s) 160. By varying the amount of computational power made available for the second computational resource, the returns on performance improvement from assigning more computational power to the accelerators 160 can be evaluated.

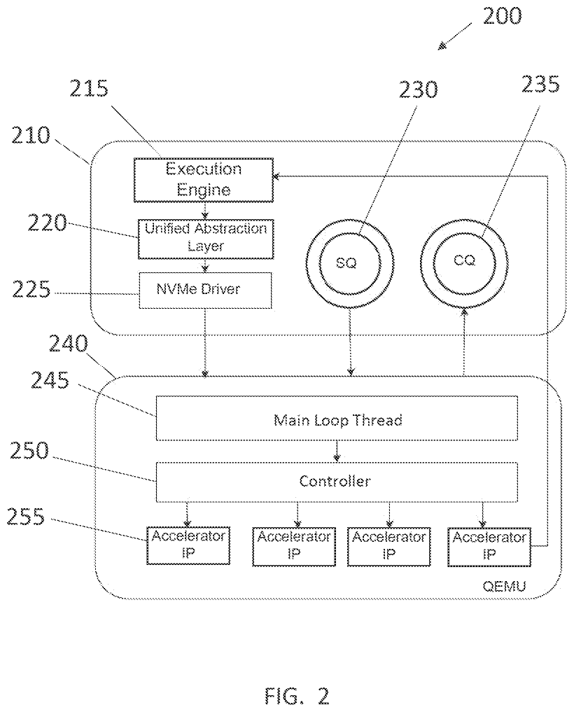

It is appreciated that the host device 110 and the hardware emulator 120 can be configured to transmit data via direct memory access (DMA), and the host device 110 can be configured to receive a Completion Queue Entry (CQE) for recording a completion of an offloading operation, as further discussed below in FIG. 2. In an embodiment, the hardware emulator 120 provides a controller module 130 that includes a controller 135, a main loop thread 140, and an emulator firmware 150.

The controller module 130 is configured to receive and/or parse the offloading commands from the host device 110 and/or otherwise provided to the hardware emulator 120 and instruct offloaded functions to be performed for data processing in an emulation of one or more accelerators (e.g., the accelerators 160).

In an embodiment, the controller module 130 can operate on a physical or hardware system that provides computational power by one or more computational resources. The computational resource can be a CPU having one or more cores providing one or more computational threads. It is appreciated that, the controller module 130 can be configured such that, a first computational resource of the hardware emulator 120 operates the controller module 130, and a second computational resource of the hardware emulator 120 operates the emulation of the one or more accelerators 160. In an embodiment, a separate computational resource of the hardware emulator 120 is provided respectively for each of the emulated accelerators 160 and the hardware emulator 120. In an embodiment, an emulator thread operates the controller module 130, an accelerator thread (different from the emulator thread) operates the emulated accelerator 160, and/or a respective accelerator thread each operates one of a plurality of emulated accelerators 160. Computational resources may be added or removed from the hardware emulator 120 to increase or decrease the computational power available to the hardware emulator 120, for example, by increasing or decreasing the number of cores in the CPU for the hardware emulator 120, increasing or decreasing the number of cores activated in the CPU for the hardware emulator 120, replacing the CPU with a CPU having more or less cores, or the like.

The controller 135 is provided in the controller module 130 as an emulation by the hardware emulator 120. In an embodiment, the controller 135 is configured to receive and/or parse commands. In an embodiment, the commands can be one or more offloading commands received from the host device 110. The controller 135 can deliver the command for being executed by other components in the hardware emulator 120. The controller module 130 can provide instructions to the one or more accelerators 160 to perform the offloaded functions. In an embodiment, the offloaded functions can include decompressing, decoding, filtering, and/or the like. The offloaded functions and/or the emulation of the accelerator 160, or the like, can each be configured for different workloads, or specific data processing, to support different user applications, such as data analytics, machine learning training, video processing, or the like. For example, components that execute or process the command from the controller 135 can include the emulator firmware 150, the main loop thread 140, the accelerators 160, or the like. In an embodiment, the controller 135 is implemented to be an NVMe controller that uses NVMe protocol for receiving one or more command from the host device 110.

The main loop thread 140 includes one or more queues for arranging and/or submitting input/output (I/O) entries for execution by the emulated accelerators 160, for communication with the host device 110, and/or the like. In an embodiment, the main loop thread 140 is provided by the first computational resources of the CPU operating the hardware emulator 120. In an embodiment, the main loop thread 140 is provided by the emulator thread of the hardware emulator 120.

The emulator firmware 150 can be included in the controller module 130. The emulator firmware 150 can include one or more low level instructions for operating the hardware emulator 120, the emulation of the one or more accelerators 160, or the like.

The one or more accelerators 160 execute one or more data operating functions. In an embodiment, the accelerator 160 executes an offloaded data operating function according to an offloading command received from another device. The accelerator 160 can be an emulated device provided by the hardware emulator 120, e.g., in a QEMU environment.

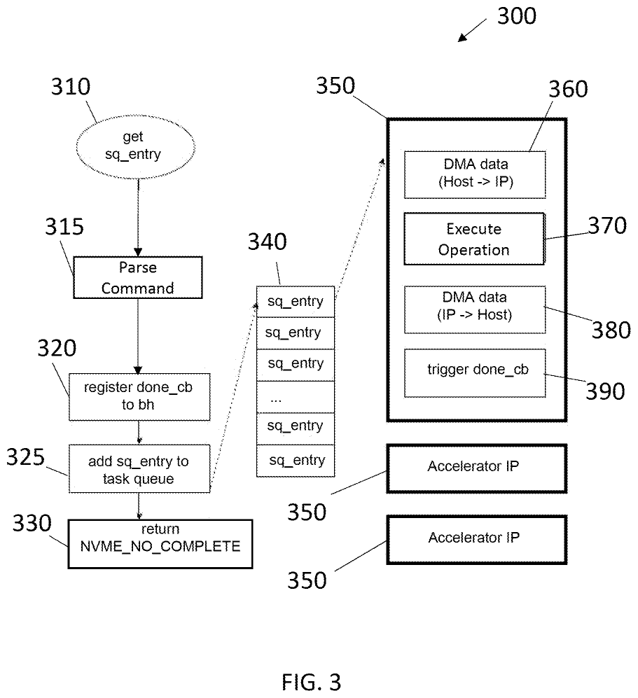

In an embodiment, the accelerator 160 is emulated in QEMU and can be operated by a computational resource separated from the computational resource running the QEMU. In an embodiment, the computational resource is a physical computational resource provided by the hardware structure of the hardware emulator 120. For example, the computational resource running the accelerator 160 can be one or more threads provided by cores of the CPU operating the hardware emulator 120, as opposed to a virtual CPU thread emulated by the hardware emulator 120. The accelerators 160 can be operated on one or more accelerator threads as further discussed below in FIG. 3.

FIG. 2 is a schematic diagram for data flow in an emulation platform 200, according to an embodiment. The emulation platform 200 can be the emulation platform 100 as described above and shown in FIG. 1.

As shown in FIG. 2, the emulation platform 200 includes a host device 210 and a hardware emulator 240. In an embodiment, the host device 210 can be the host device 110 and the hardware emulator 240 can be the hardware emulator 120 of FIG. 1 and described above.

An execution engine 215 is configured to run on the host device 210 that emulate the communication of a data processing operation. The data processing operation can request a data processing function that can be offloaded to a hardware accelerator. The data processing operation may be originated to support an application ran on the host device 210. In an embodiment, the execution engine 215 can emulate the performance of one or more functions that sends or requests the data processing operations to be executed by an emulated component (e.g., the accelerator 255) in the hardware emulator 120.

In an embodiment, the host device 210 can be implemented as an NVMe device that includes a NVMe Driver 225, a submission queue (SQ) 230, and a completion queue (CQ) 235. An execution engine 215 can run on the host device 210 that issues offloading commands. In an embodiment, the execution engine 215 can be a unified execution engine for data processing and management. In an embodiment, the host device 210 can be a physical device or an emulation on the hardware emulator 240.

A uniformed abstract layer 220 is configured to receive the command from the execution engine 215. The uniformed abstract layer 220 can be a translator or transcriber that converts the command issued by the execution engine 215 to one or more commands readable and/or receivable by a driver 225.

In an embodiment, the driver 225 is an NVMe driver for interfacing between the host device 210, the hardware emulator 240, and/or one or more accelerators 255. In an embodiment, the host device 210, the hardware emulator 240, and/or the one or more accelerators 255 can be implemented as NVMe devices.

In an embodiment, the host device 210 implemented as an NVMe device can include the SQ 230 for sending one or more entries to the hardware emulator 240, and the CQ 235 for receiving one or more entries from the hardware emulator 240. The host device 210 can transmit the command to the hardware emulator 240, e.g., through the driver 225.

The hardware emulator 240 includes a main loop thread 245 for managing I/O entries. For example, when the controller 250 becomes available, the main loop thread 245 is configured to de-queue one or more entries to the controller 250, process data transmission, perform other controller functions for the hardware emulator 240, or the like.

The controller 250 includes one or more instructions configured to parse one or more commands. For example, the controller 250 includes include instructions for parsing offloading commands into data offloading operations. In an embodiment, the controller 250 receives the command from the host device 210 delivered through the main loop thread 245. The controller 250 uses the main loop thread 245 for parsing the command to one or more data processing operations according to the one or more commands from the host device 210, and/or instructing the one or more accelerators 255 to execute the data processing functions according to the data processing functions operations parsed from the commands.

The accelerators 255 are configured to received data and execute a data operation function to the received data according to the offloading command. The accelerators 255 processes the received data according to obtain proceeded data. The accelerators 255 can receive or acquire the data to be processed from the host device 210, e.g., by direct data accessing (DMA). Once the data processing is complete, the accelerator 255 can return the processed data to the host device 210, e.g., by DMA. In an embodiment, once the data processing is complete the hardware accelerator 255 transmits a processing complete input to the CQ 235 for sending a processing complete message to the host device 210.

FIG. 3 illustrates data process flow in an emulation platform 300, according to an embodiment. The emulation platform can be the emulation platform 100, 200, or the like as discussed above in FIG. 1 or FIG. 2.

As shown in FIG. 3, the data flow of the emulation platform 300 can include data flow on the main loop thread and/or on custom threads for one more emulations of accelerators 350. In an embodiment, the main loop thread can be the main loop thread 140, 245, or the like, and the accelerators 350 can be the accelerators 160, 225, or the like, as discussed above and shown in FIG. 1 or FIG. 2

The main loop thread includes 310, 315, 320, 325, 330, and 340. At 310, the main loop thread receives an entry, e.g., from the SQ of a NVMe device (e.g., the SQ 230 of the host device of FIG. 2). The entry can include a data operation command offloaded from a host device. The data operation command can correspond to an offloading operation originated from the host device (e.g., the host device 210 of FIG. 2). Then, the main loop thread proceeds to 315.

At 315, the main loop thread parses the command, for example, using instructions on the controller (e.g., controller 250 of FIG. 2) to obtain a parsed command corresponding to the received command. The parsed command can be commands and/or instructions that are executable by the accelerators 350. The parsed command can include one or more commands for data processing operations that include, e.g., decompressing, filtering, decoding, or the like. Then, the main loop thread proceeds to 320.

At 320, the main loop thread registers a call back function to be triggered, for example, by the completion of the command. Then, the main loop thread proceeds to 325. At 325, the main loop thread adds the parsed command to a task queue 340 and proceeds to 330, once the parsed command is completed and triggering the callback function.

At 330, the main loop thread issues a processing complete entry to the host device, for example, to the CQ of an NVMe host device.

The task queue 340 can be a queue for providing entries for the operation of the accelerators 350. The task queue 340 can include one or more positions in the task queue 340 for storing entries and/or commands transmitted from the SQ. When the accelerator 350 becomes available, the task queue 340 can provide an entry or command to the accelerators 350 for execution. It is appreciated that the task queue 340 can be configured to provide one or more entries to one or more accelerators 350.

The accelerator 350 can be provided with a computational resource for operating the accelerator 350 (e.g., an accelerator thread) in executing the one or more commands provided by the entry from the task queue 340. The accelerator thread includes 360, 370, 380, and 390. It is appreciated that the accelerator thread can be a dedicated and/or assigned computational resources provided to the accelerator 350.

In an embodiment, the accelerator thread is provided by a physical CPU having a plurality of cores providing a plurality of threads. One or more of the plurality of threads may be assigned to the accelerator 350 to be the accelerator thread. Emulation of increasing or decreasing the number of threads, or adjusting the computational power of the computational resource, provided to the accelerator 350 can be conducted to evaluate the performance of the accelerator 350 relative to the computational power available to the accelerator 350. Such adjustment on an emulation can be relatively quicker and less expensive than adjusting the computational resources on a physical prototype of an accelerator. Such emulation can be configured for determining a suitable amount of computational power for an accelerator design while balancing the associated fiscal, energy, and/or computational cost.

At 360, the accelerator thread receives data for being processed by the accelerator 350. In an embodiment, the accelerator thread retrieves data stored on a host device (e.g., host device 210 of FIG. 2) by DMA. Then, the accelerator thread proceeds to 370.

At 370, the accelerator 350 executes data processing function, according to the parsed command. It is appreciated that the accelerator 350 can be dedicated to one data processing function (e.g., decompressing) such that the main loop thread distributes the processing function to a task queue of the corresponding accelerator 350. At 370, the retrieved data is processed by the accelerator 350 to obtain processed data according to one or more offloading commands. Then, the accelerator thread proceeds to 380.

At 380, the accelerator thread sends the processed data to the host device (e.g., host device 210 of FIG. 2). In an embodiment, the accelerator thread sends processed data to the host device by DMA. Then, the accelerator thread proceeds to 390.

At 390, the accelerator thread triggers a callback function to the main loop thread to indicate a completion of the data processing command. Then, the task queue 340 can transmit the next entry of parsed command to the accelerator 350 for processing. The accelerator thread may return to 360 for executing the parsed command.

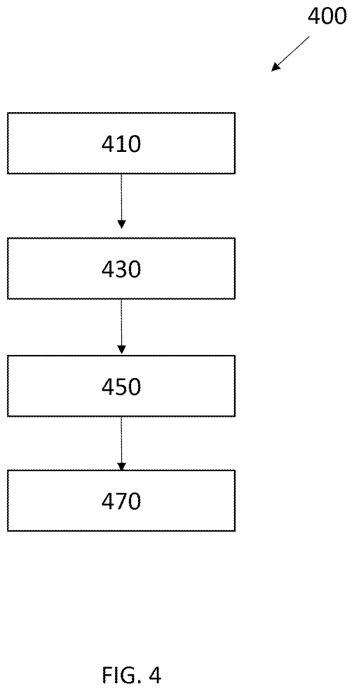

FIG. 4 is a flowchart for illustrating a method 400 of emulating hardware offloading, according to an embodiment. The method 400 starts at 410. At 410, the method 400 includes running a hardware emulator on a first computational resource of a plurality of computational resources. The first computational resource can be the main loop thread that operate and/or control the hardware emulator 120, 240, or the like as described above and shown, e.g., in FIGS. 1-3. The method 400 then proceeds to 430. At 430, the method 400 includes emulating an accelerator. The emulation of an accelerator can be provided, for example, by an QEMU emulator. Then, the method 400 proceeds to 450. At 450, the method 400 includes running the accelerator on a second computational resource of the plurality of computational resources. It is appreciated that second computational resource (e.g., an accelerator thread) is different from the first computational resource. Then, the method 400 proceeds to 470. At 479, the method includes executing an offloading command using the accelerator.

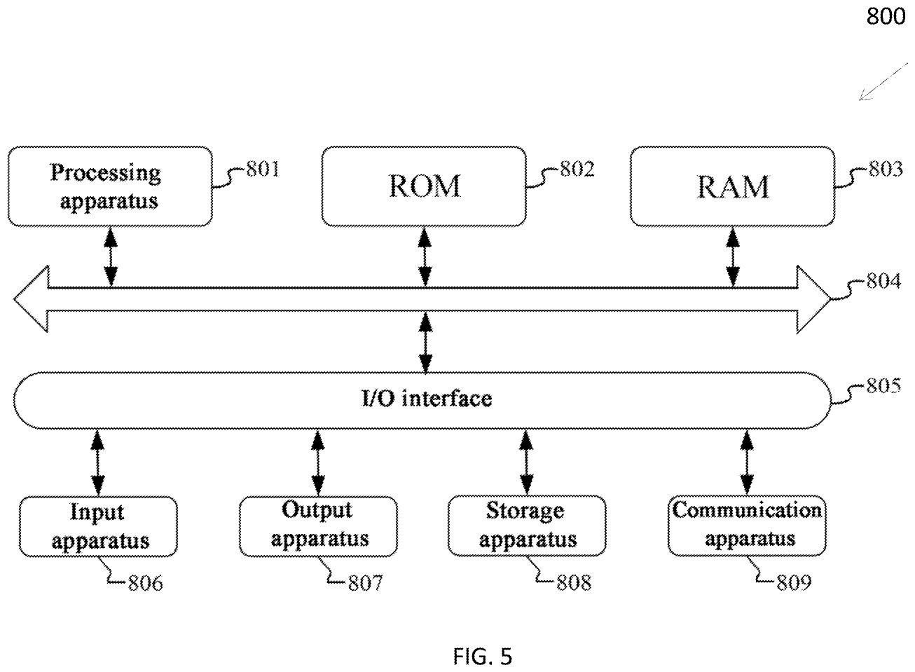

FIG. 5 illustrates a schematic structural diagram of an electronic device 800, according to an embodiment. The electronic device 800 can be a computer, a terminal, a server or the like. The electronic device 800 is suitable for implementing the embodiments of the present disclosure. The terminal device in the embodiments of the present disclosure may include, but is not limited to, mobile terminals such as a mobile phone, a notebook computer, a digital broadcast receiver, a PDA (personal digital assistant), a PAD (tablet computer), a PMP (portable multimedia player), a vehicle-mounted terminal (e.g., a vehicle-mounted navigation terminal), and the like, and fixed terminals such as a digital TV and a desktop computer. The electronic device shown in FIG. 5 is an example, and should not bring any limitation to the functions and use ranges of the embodiments of the present disclosure.

As shown in FIG. 5, the electronic device 800 includes a processing apparatus (e.g., a central processing unit (CPU), a graphics processing unit or the like) 801, which can execute various appropriate actions and processing according to programs stored in a read-only memory (ROM) 802 or programs loaded from a storage apparatus 808 into a random access memory (RAM) 803. In the RAM 803, various programs and data necessary for the operations of the electronic device 800 may be stored. The processing apparatus 801, the ROM 802 and the RAM 803 are connected with each other by means of a bus 804. An I/O interface 805 is also connected to the bus 804.

Generally, the following apparatuses may be connected to the I/O interface 805: an input apparatus 806, including, for example, a touch screen, a touchpad, a keyboard, a mouse, a camera, a microphone, an accelerometer, a gyroscope, and/or the like; an output apparatus 807, including, for example, a liquid crystal display (LCD), a speaker, a vibrator, and/or the like; the storage apparatus 808, including, for example, a magnetic tape, a hard disk, and/or the like; and a communication apparatus 809. The communication apparatus 809 allows the electronic device 800 to perform wireless or wired communication with other devices, e.g., to exchange data. Although FIG. 5 illustrates the electronic device 800 having various apparatuses, it is appreciated that, it is not required to implement or have all illustrated apparatuses. More or fewer apparatuses may be alternatively implemented or provided.

In particular, according to the embodiments of the present disclosure, the process described above with reference to the flowchart may be implemented as a computer software program. For example, the embodiments of the present disclosure include a computer program product, which includes a computer program carried on a non-transitory computer-readable medium, and the computer program contains program codes for executing the method shown in the flowchart. In such embodiments, the computer program may be downloaded and installed from a network by means of the communication apparatus 809, or installed from the storage apparatus 808, or installed from the ROM 802. When executed by the processing apparatus 801, the computer program executes the above functions defined in the method in the embodiments of the present disclosure.

It should be noted that, the above computer-readable medium in the present disclosure may be a computer-readable signal medium or a computer-readable storage medium, or any combination of thereof. The computer-readable storage medium may be, for example, but is not limited to, electrical, magnetic, optical, electromagnetic, infrared, or semiconductor systems, apparatuses or devices, or any combination thereof. More specific examples of the computer-readable storage medium may include, but are not limited to, an electrical connection with one or more wires, a portable computer disk, a hard disk, a random access memory (RAM), a read-only memory (ROM), an erasable programmable read-only memory (EPROM or a flash memory), an optical fiber, a portable compact disk-read-only memory (CD-ROM), an optical storage device, a magnetic storage device, or any suitable combination thereof. In the present disclosure, the computer-readable storage medium may be any tangible medium that contains or stores programs, and the programs may be used by or combined with instruction execution systems, apparatuses or devices for use. In the present disclosure, the computer-readable signal medium may include a data signal which is propagated in a baseband or as part of a carrier, in which computer-readable program codes are carried. Such a propagated data signal may take a variety of forms, including, but not limited to, electromagnetic signals, optical signals, or any suitable combination thereof. The computer-readable signal medium may also be any computer-readable medium other than the computer-readable storage medium, and the computer-readable signal medium may send, propagate, or transmit programs for use by or in combination with the instruction execution systems, apparatuses or devices. The program codes contained on the computer-readable medium may be transmitted by using any suitable medium, including, but not limited to: an electric wire, an optical cable, RF (radio frequency), and the like, or any suitable combination of thereof.

In some implementations, the terminal and the server may communicate by using any currently known or future developed network protocol, such as an HTTP (HyperText Transfer Protocol, hypertext transfer protocol), and may be interconnected with a digital data communication (e.g., a communication network) of any form or medium. Examples of the communication network include a local area network (“LAN”), a wide area network (“WAN”), Internet network (e.g., the Internet), an end-to-end network (e.g., an ad hoc end-to-end network), as well as any currently known or future developed network.

The computer-readable medium may be contained in the electronic device; and may also exist alone, but is not assembled in the electronic device. In an embodiment, the computer-readable medium carries one or more programs, and when the one or more programs are executed by the electronic device, the electronic device executes the following operations: run a hardware emulator on a first computational resource of a plurality of computational resources; emulate an accelerator; run the accelerator on a second computational resource of the plurality of computational resources; and execute an offloading command using the accelerator.

Computer program codes for executing the operations of the present application may be written in one or more programming languages or combinations thereof, the programming languages include, but are not limited to, object-oriented programming languages, such as Java, Smalltalk and C++, and also include conventional procedural programming languages, such as “C” language or similar programming languages. The program codes may be completely executed on a user computer, partly on the user computer, as a stand-alone software package, partly on the user computer and partly on a remote computer, or completely on the remote computer or a server. In the case involving the remote computer, the remote computer may be connected to the user computer by means of any kind of network, including a local area network (LAN) or a wide area network (WAN), or may be connected to an external computer (e.g., connected by means of the Internet by using an internet service provider).

The flowcharts and block diagrams in the drawings illustrate system architectures, functions and operations that may be implemented by the systems, methods and computer program products according to various embodiments of the present disclosure. In this regard, each block in the flowcharts or block diagrams may represent a part of a module, a program segment or a code, and a part of the module, the program segment or the code contains one or more executable instructions for implementing specified logical functions. It should also be noted that, in some alternative implementations, functions annotated in the blocks may also occur in a different order from those annotated in the drawings. For example, two consecutive blocks may, in fact, be executed substantially in parallel, and may also be executed in a reverse order sometimes, depending upon the functions involved. It should also be noted that, each block in the block diagrams and/or flowcharts, and combinations of the blocks in the block diagrams and/or flowcharts may be implemented by dedicated hardware-based systems, which are used for executing the specified functions or operations, or may be implemented by a combination of dedicated hardware and computer instructions.

The modules involved in the description of the embodiments of the present disclosure may be implemented in a software manner, and may also be implemented in a hardware manner. In some cases, the name of the module does not constitute a limitation on the module itself.

The above functions described herein may be executed, at least in part, by one or more hardware logic components. For example, non-restrictively, available hardware logic components of an exemplary type include: a field-programmable gate array (FPGA), an application-specific integrated circuit (ASIC), an application-specific standard product (ASSP), an on-chip system (SOC), a complex programmable logic device (CPLD), or the like.

In an embodiment, a machine-readable medium may be a tangible medium, which may contain or store programs for use by or in combination with instruction execution systems, apparatuses or devices. The machine-readable medium may be a machine-readable signal medium or a machine-readable storage medium. The machine-readable medium may include, but is not limited to, electronic, magnetic, optical, electromagnetic, infrared, or semiconductor systems, apparatuses or devices, or any suitable combination of thereof. More specific examples of the machine-readable storage medium may include an electrical connection based on one or more wires, a portable computer disk, a hard disk, a random access memory (RAM), a read-only memory (ROM), an erasable programmable read-only memory (EPROM or a flash memory), an optical fiber, a portable compact disk-read-only memory (CD-ROM), an optical storage device, a magnetic storage device, or any suitable combination of thereof.

The above description is merely illustration of preferred embodiments of the present disclosure and the applied technical principles. It should be understood by those skilled in the art that, the scope of disclosure involved in the present disclosure is not limited to technical solutions formed by particular combinations of the above technical features, and should also cover other technical solutions formed by any combination of the above technical features or equivalent features thereof without departing from the above disclosed concepts, for example, technical solutions formed by replacing the above features with technical features having similar functions disclosed in the present disclosure (but not limited to).

In addition, although various operations are depicted in a particular order, it should not be understood that these operations are required to be executed in the shown particular order or in sequential order. In certain environments, multitasking and parallel processing may be advantageous. Likewise, although several specific implementation details are contained in the above discussion, these should not be construed as limiting the scope of the present disclosure. Some features described in the context of separate embodiments may also be implemented in combination in a single embodiment. Conversely, various features described in the context of a single embodiment may also be implemented in a plurality of embodiments separately or in the form of any suitable sub-combination.

Although the present theme has been described in a language specific to structural features and/or method logical actions, it should be understood that the theme defined in the appended claims is not necessarily limited to the particular features or actions described above. Rather, the particular features or actions described above are merely exemplary forms of implementing the claims. With regard to the apparatus in the above embodiments, the specific manner in which each module executes operations has been described in detail in the embodiments related to the method, and thus will not be described in detail herein.

It is to be understood that the disclosed and other solutions, examples, embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., a field programmable gate array, an application specific integrated circuit, or the like.

Processors suitable for the execution of a computer program include, by way of example, both general and special purpose microprocessors, and any one or more processors of any kind of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., erasable programmable read-only memory, electrically erasable programmable read-only memory, and flash memory devices; magnetic disks, e.g., internal hard disks or removable disks; magneto optical disks; and compact disc read-only memory and digital video disc read-only memory disks. The processor and the memory can be supplemented by, or incorporated in, special purpose logic circuitry.

It is to be understood that different features, variations and multiple different embodiments have been shown and described with various details. What has been described in this application at times in terms of specific embodiments is done for illustrative purposes only and without the intent to limit or suggest that what has been conceived is only one particular embodiment or specific embodiments. It is to be understood that this disclosure is not limited to any single specific embodiments or enumerated variations. Many modifications, variations and other embodiments will come to mind of those skilled in the art, and which are intended to be and are in fact covered by both this disclosure. It is indeed intended that the scope of this disclosure should be determined by a proper legal interpretation and construction of the disclosure, including equivalents, as understood by those of skill in the art relying upon the complete disclosure present at the time of filing.

Aspects: It is noted that any one of aspects 1-8 below can be combined with any of aspects 9-15 and/or any of aspects 16-20.

Aspect 1. A platform for emulating a hardware accelerator, when executed by a computer, the platform comprising:
a hardware emulator, configured to emulate an accelerator, operated on a first computational resource of a plurality of computational resources provided by the computer; and
the accelerator being emulated in the platform and operated on a second computational resource of the plurality of computational resources, the accelerator being configured to emulate an execution of an offloading operation by the second computational resource that is separate from the first computational resource.

Aspect 2. The platform of aspect 1, wherein
the hardware emulator includes a quick emulator (QEMU) providing an emulation of a controller operating on the first computational resource; and
the QEMU emulates the accelerator for an emulation of executing the offloading operation on the second computational resource.

Aspect 3. The platform of aspect 1 or 2, wherein the accelerator comprises:
the offloading operation includes decompressing, filtering, or decoding.

Aspect 4. The platform of any one of aspects 1-3, wherein the accelerator is emulated as an NVMe device, and the hardware emulator emulates an NVMe controller for an emulation of receiving an offloading command for performing the offloading operation.

Aspect 5. The platform of any one of aspects 1-4, wherein the hardware emulator emulates a firmware having instructions for an emulation of operating the accelerator to execute the offloading operation.

Aspect 6. The platform of any one of aspects 1-5, wherein the hardware emulator is provided with a main loop thread, ran by the first computational resource, for emulating receiving of an offloading command for emulating an execution of the offloading operation, and for emulating providing a callback function for communicating a function complete message.

Aspect 7. The platform of any one of aspects 1-6, further comprising:
the hardware emulator is provided with a main loop thread, ran by the first computational resource, for emulating parsing of an offloading command.

Aspect 8. The platform of any one of aspects 1-7, wherein the platform is configured to adjust a computational power available to the accelerator for evaluating offloading performance of the accelerator relative to an amount of the computational power available to the accelerator.

Aspect 9. A method of emulating hardware offloading, the method comprising:
emulating a running of a hardware emulator on a first computational resource of a plurality of computational resources;
emulating an accelerator;
emulating a running of the accelerator on a second computational resource of the plurality of computational resources; and
emulating an executing an offloading command using the accelerator.

Aspect 10. The method of aspect 9, wherein the offloading command comprises decompressing, filtering, or decoding.

Aspect 11. The method of aspect 9 or 10, further comprising
emulating a receiving of the offloading command from a host device communicating with the hardware emulator.

Aspect 12. The method of any one of aspects 9-11, further comprising
emulating a transmitting of the offloading command to a main loop thread run by the first computational resource;
emulating a receiving of the offloading command for performing an offloading operation; and
   instructing the accelerator to execute the offloading operation according to the offloading command.

Aspect 13. The method of any one of aspects 9-12, further comprising:
emulating a triggering of a callback function to communicate a function complete message to a host device when an offloading operation is completed according to the offloading command.

Aspect 14. The method of any one of aspects 9-13, further comprising
emulating a recording of a processing time for executing the offloading command using the accelerator.

Aspect 15. The method of any one of aspects 9-14, further comprising
adjusting an amount of computational power available to the second computational resource for evaluating offloading performance of the accelerator relative to an amount of the computational power available to the accelerator.

Aspect 16. A computer-readable medium containing instructions that, when executed by a processor, direct the processor to:
run a hardware emulator on a first computational resource of a plurality of computational resources;
emulate an accelerator;
emulate an operation of the accelerator on a second computational resource of the plurality of computational resources; and
   emulate an execution of an offloading command using the accelerator.

Aspect 17. The computer-readable medium of aspect 16 further containing instructions that, when executed by the processor, direct the processor to:
emulate a receiving of the offloading command from a host device communicating with the hardware emulator.

Aspect 18. The computer-readable medium of aspect 16 or 17 further containing instructions that, when executed by the processor, direct the processor to:
emulate a transmission of the offloading command to a main loop thread run by the first computational resource;
emulate a receiving of the offloading command to obtain an offloading operation; and
emulate an instruction of the accelerator to execute the offloading operation.

Aspect 19. The computer-readable medium of any one of aspects 16-18 further containing instructions that, when executed by the processor, direct the processor to:
emulate a receiving of data by direct memory access (DMA) from a host device;
emulate a processing of the data according to the offloading command to obtain processed data;
emulate a sending of the processed data by DMA to the host device; and
emulate a triggering of a callback function to communicate a function complete message to the host device.

Aspect 20. The computer-readable medium of any one of aspects 16-19 further containing instructions that, when executed by the processor, direct the processor to:
adjust an amount of computational power available to the second computational resource for evaluating offloading performance of the accelerator relative to an amount of the computational power available to the accelerator.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A platform for emulating a hardware accelerator, when executed by a computer, the platform comprising:
a hardware emulator, configured to emulate an accelerator, operated on a first computational resource of a plurality of computational resources provided by the computer; and
the accelerator being emulated in the platform and operated on a second computational resource of the plurality of computational resources, the accelerator being configured to emulate an execution of an offloading operation by the second computational resource that is separate from the first computational resource.

2. The platform of claim 1, wherein
the hardware emulator includes a quick emulator (QEMU) providing an emulation of a controller operating on the first computational resource; and
the QEMU emulates the accelerator for an emulation of executing the offloading operation on the second computational resource.

3. The platform of claim 1, wherein the offloading operation includes decompressing, filtering, or decoding.

4. The platform of claim 1, wherein the accelerator is emulated as an NVMe device, and the hardware emulator emulates an NVMe controller for an emulation of receiving an offloading command for performing the offloading operation.

5. The platform of claim 1, wherein the hardware emulator emulates a firmware having instructions for an emulation of operating the accelerator to execute the offloading operation.

6. The platform of claim 1, wherein
the hardware emulator is provided with a main loop thread, ran by the first computational resource, for emulating receiving of an offloading command for emulating an execution of the offloading operation, and for emulating providing a callback function for communicating a function complete message.

7. The platform of claim 1, further comprising:
the hardware emulator is provided with a main loop thread, ran by the first computational resource, for emulating parsing of an offloading command.

8. The platform of claim 1, wherein
the platform is configured to adjust a computational power available to the accelerator for evaluating offloading performance of the accelerator relative to an amount of the computational power available to the accelerator.

9. A method of emulating hardware offloading, the method comprising:
emulating a running of a hardware emulator on a first computational resource of a plurality of computational resources;
emulating an accelerator;
emulating a running of the accelerator on a second computational resource of the plurality of computational resources; and
emulating an executing an offloading command using the accelerator.

10. The method of claim 9, wherein the offloading command comprises decompressing, filtering, or decoding.

11. The method of claim 9, further comprising
emulating a receiving of the offloading command from a host device communicating with the hardware emulator.

12. The method of claim 9, further comprising
emulating a transmitting of the offloading command to a main loop thread run by the first computational resource;
emulating a receiving of the offloading command for performing an offloading operation; and
instructing the accelerator to execute the offloading operation according to the offloading command.

13. The method of claim 9, further comprising:
emulating a triggering of a callback function to communicate a function complete message to a host device when an offloading operation is completed according to the offloading command.

14. The method of claim 9, further comprising
emulating a recording of a processing time for executing the offloading command using the accelerator.

15. The method of claim 9, further comprising
adjusting an amount of computational power available to the second computational resource for evaluating offloading performance of the accelerator relative to an amount of the computational power available to the accelerator.

16. A computer-readable medium containing instructions that, when executed by a processor, direct the processor to:
run a hardware emulator on a first computational resource of a plurality of computational resources;
emulate an accelerator;
emulate an operation of the accelerator on a second computational resource of the plurality of computational resources; and
emulate an execution of an offloading command using the accelerator.

17. The computer-readable medium of claim 16 further containing instructions that, when executed by the processor, direct the processor to:
emulate a receiving of the offloading command from a host device communicating with the hardware emulator.

18. The computer-readable medium of claim 16 further containing instructions that, when executed by the processor, direct the processor to:
emulate a transmission of the offloading command to a main loop thread run by the first computational resource;
emulate a receiving of the offloading command to obtain an offloading operation; and
emulate an instruction of the accelerator to execute the offloading operation.

19. The computer-readable medium of claim 16 further containing instructions that, when executed by the processor, direct the processor to:
emulate a receiving of data by direct memory access (DMA) from a host device;
emulate a processing of the data according to the offloading command to obtain processed data;
emulate a sending of the processed data by DMA to the host device; and
emulate a triggering of a callback function to communicate a function complete message to the host device.

20. The computer-readable medium of claim 18 further containing instructions that, when executed by the processor, direct the processor to:
adjust an amount of computational power available to the second computational resource for evaluating offloading performance of the accelerator relative to an amount of the computational power available to the accelerator.
